(19) United States
(12) Patent Application Publication
(10) Pub. No.: US 2023/0089142 A1
(43) Pub. Date: Mar. 23, 2023

(54) SEMICONDUCTOR STRUCTURE AND METHOD FOR FABRICATING SEMICONDUCTOR STRUCTURE

(71) Applicant: CHANGXIN MEMORY TECHNOLOGIES, INC., Hefei (CN)

(72) Inventors: SEMYEONG JANG, Hefei (CN); JOONSUK MOON, Hefei (CN); Deyuan XIAO, Hefei (CN); SOONBYUNG PARK, Hefei (CN); JO-LAN CHIN, Hefei (CN)

(21) Appl. No.: 17/892,152

(22) Filed: Aug. 22, 2022

(30) Foreign Application Priority Data
Sep. 17, 2021 (CN) 202111090856.9

(51) Int. Cl. H01L 27/108

(52) U.S. Cl. CPC H01L 27/10873; H01L 27/10814

(57) ABSTRACT

Embodiments provide a semiconductor structure and a method for fabricating a semiconductor structure. The semiconductor structure includes a substrate, where a plurality of trenches are crisscross arranged in the substrate, such that a plurality of silicon pillars are formed on the substrate, and each of the plurality of trenches is filled with a spacer. A conductive layer is arranged at a top of a given one of the plurality of silicon pillars, where the conductive layer covers a top surface of the given silicon pillar and a partial side surface thereof adjacent to the top surface, and the conductive layer is configured to contact with a capacitor.

### CROSS-REFERENCE TO RELATED APPLICATION

This application claims priority to Chinese Patent Application No. 202111090856.9, titled “SEMICONDUCTOR STRUCTURE AND METHOD FOR FABRICATING SEMICONDUCTOR STRUCTURE” and filed to the State Patent Intellectual Property Office on Sep. 17, 2021, the entire contents of which are incorporated herein by reference.

### TECHNICAL FIELD

The present disclosure relates to the technical field of semiconductors, and more particularly, to a semiconductor structure and a method for fabricating a semiconductor structure.

BACKGROUND

In existing Vertical Gate All Around (VGAA) technologies, a mainstream design of capacitive contact is as below: a capacitive metal is only contacted on a top surface of a silicon pillar of a transistor by means of an exposure alignment sequence. However, as an area of the top surface of the silicon pillar is smaller, a contact resistance between the silicon pillar and a capacitor is larger, which has a negative effect on device performance.

### SUMMARY

One major objective of the present disclosure is to provide a semiconductor structure having a smaller contact resistance between a silicon pillar and a capacitor by overcoming at least one defect in the prior art.

Another major objective of the present disclosure is to provide a method for fabricating a semiconductor structure capable of reducing the contact resistance between the silicon pillar and the capacitor by overcoming at least one defect in the prior art.

To achieve the above objectives, the present disclosure adopts the following technical solutions.

According to one aspect of the present disclosure, there is provided a semiconductor structure, which includes a substrate. A plurality of trenches are crisscross arranged in the substrate, such that a plurality of silicon pillars are formed on the substrate, and each of the plurality of trenches is filled with a spacer. A conductive layer is arranged at a top of a given one of the plurality of silicon pillars, where the conductive layer covers a top surface of the given silicon pillar and a partial side surface thereof adjacent to the top surface, and the conductive layer is configured to contact with a capacitor.

According to another aspect of the present disclosure, there is provided a method for fabricating a semiconductor structure. The method includes: providing a substrate, where a plurality of trenches are crisscross arranged in the substrate, such that a plurality of silicon pillars are formed on the substrate; forming a spacer, where the spacer is filled in a given one of the plurality of trenches, and a top surface of the spacer is exposed in the given trench; removing the spacer on a top surface of the given silicon pillar and the spacer on a partial side surface thereof adjacent to the top surface, and forming a pit around an top end of the given silicon pillar; and forming a conductive layer on a surface of the substrate, where the conductive layer covers the top surface of the given silicon pillar and a partial side surface thereof adjacent to the top surface.

As can be seen from the above technical solutions, advantages and positive effects of the semiconductor structure and the method for fabricating a semiconductor structure proposed in the present disclosure are as below.

According to the semiconductor structure provided by the present disclosure, a conductive layer is arranged at a top of a silicon pillar, and the conductive layer covers a top surface of the silicon pillar and a partial side surface thereof adjacent to the top surface, where the conductive layer is configured to contact with a capacitor. Through the above design, a contact area of an indirect electric contact between the given silicon pillar and the capacitor can be increased by means of a design where the conductive layer covers the top surface and the partial side surface of the given silicon pillar, such that a contact resistance between the given silicon pillar and the capacitor is reduced, and device performance is improved.

### BRIEF DESCRIPTION OF THE DRAWINGS

Various objectives, features and advantages of the present disclosure will become more apparent by considering the following detailed description of embodiments of the present disclosure with reference to the accompanying drawings. The accompanying drawings are merely exemplary illustration of the present disclosure, and are not necessarily drawn to scale. The same reference numerals in the accompanying drawings always indicate the same or similar components. In the accompanying drawings:

FIG. 1 is a schematic plan diagram showing a semiconductor structure according to an exemplary embodiment;

FIG. 2 is a schematic cross-sectional diagram taken along Line A-A in FIG. 1;

FIG. 3 is a schematic cross-sectional diagram taken along Line B-B in FIG. 1;

FIG. 4 is a schematic flow chart showing a method for fabricating a semiconductor structure according to an exemplary embodiment; and

FIGS. 5 to 13 respectively are schematic cross-sectional diagrams of the semiconductor structure in structural steps of the method for fabricating a semiconductor structure as shown in FIG. 4.

### REFERENCE NUMERALS IN THE ACCOMPANYING DRAWINGS ARE AS FOLLOWS

100-substrate;

110-trench;

111-first trench;

112-second trench;

120-silicon pillar;

121-upper portion;

122-lower portion;

123-recessed region;

200-spacer;

210-first spacer;

220-second spacer;

300-conductive layer;

301-conductive material;

400-gate-all-around structure;

401-conductive material;

500-dielectric layer;

510-first dielectric layer;

520-second dielectric layer;

BL-bit line;

WL-word line;

G-gap;

P-Pit;

S1-S4-steps.

### DETAILED DESCRIPTION

Typical embodiments embodying features and advantages of the present disclosure will be described in detail in the following specification. It is to be understood that the present disclosure may have various changes on different embodiments, which does not depart from the scope of the present disclosure, and the description and accompanying drawings therein in essence are used for illustrating but not intended for limiting the present disclosure.

In the following description of different exemplary embodiments of the present disclosure, it is made with reference to the accompanying drawings, which form a part of the present disclosure, and therein different exemplary structures, systems and steps that can implement various aspects of the present disclosure are shown by way of example. It should be understood that other solutions of components, structures, exemplary apparatuses, systems, and steps may be used, and structural and functional modifications may be made without departing from the scope of the present disclosure. Moreover, although the terms “above”, “between”, “within”, etc. may be used in this specification to describe different exemplary features and elements of the present disclosure, these terms are used herein for convenience only, such as directions of the examples in the accompanying drawings. Nothing in this specification should be understood as requiring a three-dimensional direction of the structure to fall within the scope of the present disclosure.

Referring to FIG. 1, a schematic plan view of a semiconductor structure proposed in the present disclosure is typically illustrated. In this exemplary embodiment, the semiconductor structure proposed in the present disclosure is described by taking an example where the semiconductor structure is applied to a 4F2 Vertical Gate All Around (VGAA) Dynamic Random Access Memory (DRAM) device. It is readily comprehensible to those skilled in the art that to apply relevant design of the present disclosure to other types of semiconductor structures, various modifications, additions, substitutions, deletions or other variations are made to the following embodiments, and these variations still fall within the scope of the principle of the semiconductor structure proposed in the present disclosure.

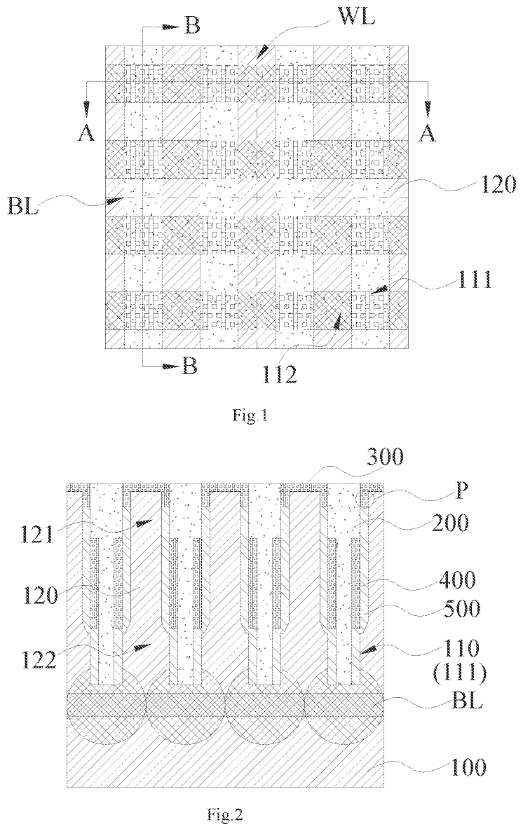

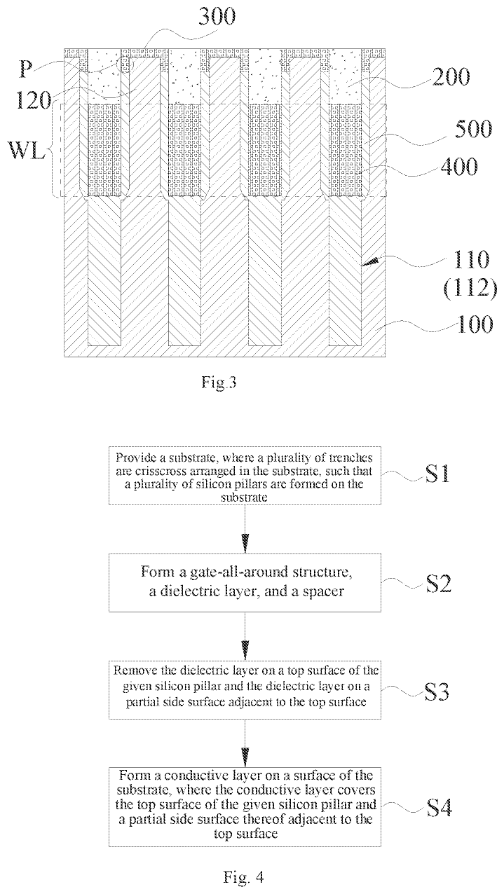

As shown in FIG. 1, in this embodiment, the present disclosure provides, for example, a 4F2 VGAA DRAM device provided with word lines WL and buried with bit lines BL in a unit device. Referring to FIG. 2 and FIG. 3 together, FIG. 2 typically illustrates a schematic cross-sectional diagram taken along Line A-A in FIG. 1; and FIG. 3 typically illustrates a cross-sectional schematic diagram taken along Line B-B in FIG. 1. Structures, arrangement modes and functional relationships between main components of the semiconductor structure proposed in the present disclosure will be described below with reference to the above drawings.

As shown in FIG. 1 to FIG. 3, in this embodiment, the semiconductor structure proposed in the present disclosure includes a substrate 100, where a plurality of trenches 110 are crisscross arranged in the substrate 100, such that a plurality of silicon pillars 120 are formed on the substrate 100, and each of the plurality of trenches 110 is filled with a spacer 200. In some embodiments, a plurality of trenches 110 may include a plurality of first trenches 111 extending along a first direction and a plurality of second trenches 112 extending a long a second direction, where the plurality of first trenches 111 corresponds to the word lines WL and the plurality of second trenches 112 corresponds to the bit lines BL. A conductive layer 300 is arranged at a top of a given one of the plurality of silicon pillars 120, where the conductive layer 300 covers a top surface of the given silicon pillar 120 and a partial side surface thereof adjacent to the top surface, and the conductive layer 300 is configured to contact with a capacitor. Accordingly, in addition to in contact with the top surface of the given silicon pillar 120, the conductive layer 300 also contacts with the partial side surface adjacent to the top surface of the given silicon pillar 120. The given silicon pillar 120 contacts with a capacitor by means of the conductive layer 300, which is equivalent to increasing an electric contact area between the given silicon pillar 120 and the capacitor, such that a contact resistance between the given silicon pillar 120 and the capacitor is reduced, and thus device performance of the semiconductor structure can be effectively improved.

As shown in FIG. 2 and FIG. 3, in this embodiment, a top surface of the spacer 200 may be flush with a top surface of the conductive layer 300.

In this embodiment, a material of the spacer 200 may be silicon nitride (SiN).

In this embodiment, a material of the conductive layer 300 may be titanium nitride (TiN). In some embodiments, the material of the conductive layer 300 may also be other metal materials, such as tungsten (W), but not limited thereto.

As shown in FIG. 2 and FIG. 3, in this embodiment, a gate-all-around structure 400 may be arranged around the given silicon pillar 120, and a dielectric layer 500 is arranged between the gate-all-around structure 400 and the given silicon pillar 120.

As shown in FIG. 2 and FIG. 3, based on the design where the dielectric layer 500 is arranged between the gate-all-around structure 400 and the given silicon pillar 120, in this embodiment, the dielectric layer 500 may cover rest of side surface of the given silicon pillar 120 not covered by the conductive layer 300.

In this embodiment, the dielectric layer 500 may be substantially equal to the conductive layer 300 in thickness. In some embodiments, the dielectric layer 500 may be not equal to the conductive layer 300 in thickness. For example, the thickness of the dielectric layer 500 is greater than that of the conductive layer 300, or the thickness of the dielectric layer 500 is smaller than that of the conductive layer 300. In addition, in the above description, the thickness of the conductive layer 300 refers to the thickness of the conductive layer 300 covering the side surface of the given silicon pillar 120 and the thickness of the conductive layer 300 covering the top surface of the given silicon pillar 120, which may be equal or not equal.

As shown in FIG. 2 and FIG. 3, in this embodiment, the given silicon pillar 120 may have an upper portion 121 and a lower portion 122. In some embodiments, the upper portion 121 is connected to an upper end of the lower portion 122, and the size of the upper portion 121 is smaller than that of the lower portion 122. On this basis, the gate-all-around structure 400 may be arranged around the upper portion 121 and positioned below the conductive layer 300 at intervals. The upper portion 121 may be understood as an outer wall of a portion of the given silicon pillar 120 including the top end being recessed inward, and compared with this portion of the original silicon pillar 120, the formed upper portion 121 is equivalent to forming the recessed region 123 encircling the given silicon pillar 120.

As shown in FIG. 2 and FIG. 3, in this embodiment, the dielectric layer 500 covering the upper portion 121 is substantially equal to the recessed region 123 of the given silicon pillar 120 in thickness. In some embodiments, the thickness of the dielectric layer 500 covering the upper portion 121 may be greater than or smaller than that of the recessed region 123 of the given silicon pillar 120 as long as there is a gap G between the dielectric layer 500 in this position and the spacer 200 to arrange the gate-all-around structure 400.

In this embodiment, a material of the gate-all-around structure 400 may be titanium nitride. In some embodiments, the material of the gate-all-around structure 400 may also be other metal materials such as tungsten, but not limited thereto.

In this embodiment, a material of the dielectric layer 500 may be silicon oxide (SiO2). In some embodiments, the material of the dielectric layer 500 may also be other materials such as other oxides, but not limited thereto.

It is to be noted here that the semiconductor structures illustrated in the drawings and described in this specification are merely a few examples of various semiconductor structures that can employ the principles of the present disclosure. It is to be clearly understood that the principles of the present disclosure are in no way limited to any details or components of the semiconductor structures illustrated in the drawings or described in this specification.

Based on the above detailed description of an exemplary embodiment of the semiconductor structure proposed in the present disclosure, an exemplary embodiment of the method for fabricating a semiconductor structure proposed in the present disclosure will be described below.

Referring to FIG. 4, a schematic flow chart of a method for fabricating a semiconductor structure proposed by the present disclosure is typically shown. In this exemplary embodiment, the semiconductor structure proposed in the present disclosure is described by taking an example where the semiconductor structure is applied to a 4F2 VGAA DRAM device. It is readily comprehensible to those skilled in the art that to apply relevant design of the present disclosure to a method for fabricating other types of semiconductor structures, various modifications, additions, substitutions, deletions or other variations are made to the following embodiments, and these variations are still within the scope of the principle of the method for fabricating a semiconductor structure proposed in the present disclosure.

As shown in FIG. 4, in this embodiment, the method for fabricating a semiconductor structure proposed in the present disclosure at least includes the following steps:

Step S1: providing a substrate 100, wherein a plurality of trenches 110 are crisscross arranged in the substrate 100, such that a plurality of silicon pillars 120 are formed on the substrate 100;

Step S2: forming a spacer 200, wherein the spacer 200 is filled in a given one of the plurality of trenches 110, and a top surface of the spacer 200 is exposed in the given trench 110;

Step S3: removing the dielectric layer 500 on a top surface of the given silicon pillar 120 and the dielectric layer 500 on a partial side surface adjacent to the top surface, and forming a pit P around an top end of the given silicon pillar 120; and

Step S4: forming a conductive layer 300 on a surface of the substrate 100, wherein the conductive layer 300 covers the top surface of the given silicon pillar 120 and a partial side surface thereof adjacent to the top surface.

Referring to FIGS. 5 to 13, FIGS. 5 to 13 respectively are schematic cross-sectional diagrams of the semiconductor structure in structural steps of the method for fabricating a semiconductor structure as shown in FIG. 4. Descriptions of structure, fabrication mode and process relationship of the semiconductor structure in major steps of the method for fabricating a semiconductor proposed in the present disclosure will be made below in combination with the above accompanying drawings.

As shown in FIGS. 5 to 11, in this embodiment, Step S2 may further include: forming a gate-all-around structure 400 and a dielectric layer, where the gate-all-around structure 400 encircles the given silicon pillar 120, the dielectric layer 500 is arranged between the gate-all-around structure 400 and the given silicon pillar 120, and the dielectric layer 500 covers a side surface and the top surface of the given silicon pillar 120 and is positioned between the gate-all-around structure 400 and the given silicon pillar 120.

As shown in FIG. 5 to FIG. 11, in this embodiment, Step S2 may include the following steps:

Step S21: covering the top surface and the side surface of the given silicon pillar 120 with a dielectric material to form a first dielectric layer 510;

Step S22: filling each of the plurality of trenches 110 with a spacer material to form a first spacer 210;

Step S23: removing the first dielectric layer 510 positioned on the top surface of the given silicon pillar 120 and the first dielectric layer 510 positioned on the a partial side surface adjacent to the top surface;

Step S24: partially removing the side surface of the given silicon pillar 120 not covered by the first dielectric layer 510, and forming a second dielectric layer 520 on the top surface and the partially removed side surface of the given silicon pillar 120, where there is a gap G between the second dielectric layer 520 and the first spacer 210, and rest of first dielectric layer 510 and the second dielectric layer 520 jointly constitute the dielectric layer 500;

Step S25: forming the gate-all-around structure 400 encircling the given silicon pillar 120 in a lower space of the gap G; and

Step S26: filling an upper space of the gap G with a spacer material to form a second spacer 220, where the first spacer 210 and the second spacer 220 jointly constitute the spacer 200.

As shown in FIG. 5, a schematic cross-sectional diagram of the semiconductor structure in Step S21 is illustrated, and reference is made to FIG. 2 for a cutting direction. In Step S1, the semiconductor structure includes the substrate 100, the bit line BL, the given silicon pillar 120, and the first dielectric layer 510. In some embodiments, the bit line BL is buried in the substrate 100, a plurality of trenches 110 are formed by etching on the substrate 100, and a plurality of silicon pillars 120 are formed on the substrate 100, where the first dielectric layer 510 covers the top surface and the side surface of the given silicon pillar 120.

In Step S21, after the first dielectric layer 510 is deposited, the first dielectric layer 510 is not only formed on the top surface and the side surface of the given silicon pillar 120, but also covers a bottom wall of a given one of the plurality of trenches 110. The first dielectric layer 510 covering the bottom wall of the given trench 110 is etched and removed to obtain the first dielectric layer 510 in Step S21.

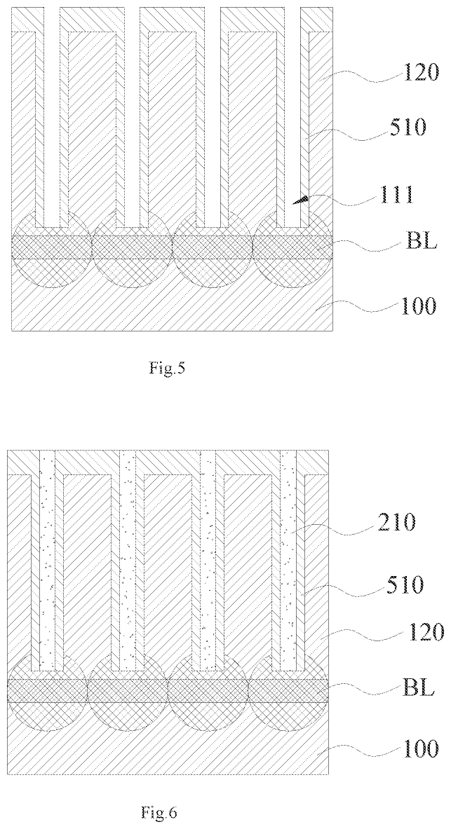

As shown in FIG. 6, a schematic cross-sectional diagram of the semiconductor structure in Step S21 is illustrated. In Step S22, the semiconductor structure includes the substrate 100, the bit line BL, the given silicon pillar 120, the first dielectric layer 510, and the first spacer 210. In some embodiments, the first spacer 210 fills into the given trench 110. It is to be noted that because the first dielectric layer 510 is formed on the top surface of the given silicon pillar 120, the given trench 110 filled with the first spacer 210 includes a space defined by this part of first dielectric layer 510.

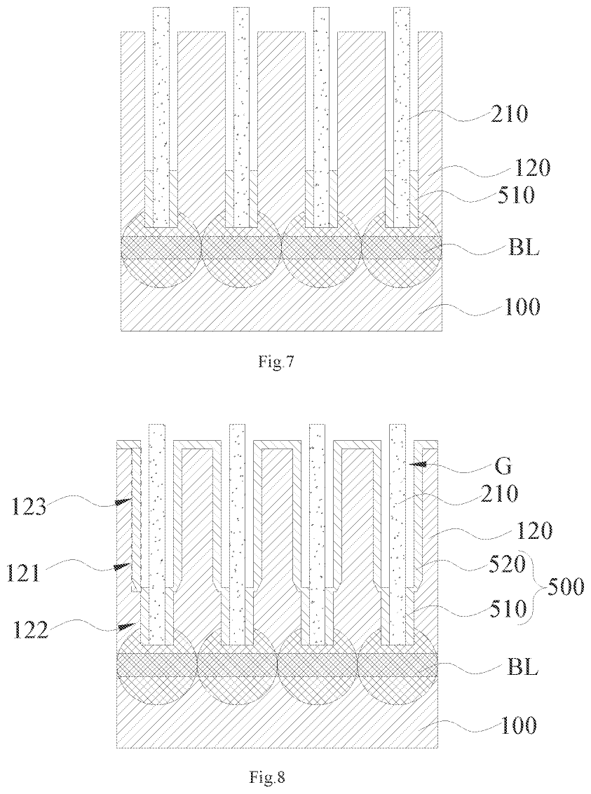

As shown in FIG. 7, a schematic cross-sectional diagram of the semiconductor structure in Step S23 is illustrated. In Step S23, the semiconductor structure includes the substrate 100, the bit line BL, the given silicon pillar 120, the first dielectric layer 510 remained after etching, and the first spacer 210. In some embodiments, the first dielectric layer 510 on the top surface of the given silicon pillar 120 and the partial side surface thereof adjacent to the top surface may be removed by means of dry etching or wet etching, etc. Moreover, after the first dielectric layer 510 is partially removed, there is a gap between the side surface of the given silicon pillar 120 not covered by the first dielectric layer 510 and the first spacer 210.

As shown in FIG. 8, a schematic cross-sectional diagram of the semiconductor structure in Step S24 is illustrated. In Step S24, the semiconductor structure includes the substrate 100, the bit line BL, the given silicon pillar 120, the first dielectric layer 510 remained after etching, the first spacer 210, and the second dielectric layer 520. In some embodiments, in Step S24, the side surface of the given silicon pillar 120 not covered by the first dielectric layer 510 is partially removed, such that a size of the part of the given silicon pillar 120 not covered by the first dielectric layer 510 is smaller than that of a rest part of the given silicon pillar 120. After Step S24, the given silicon pillar 120 includes an upper portion 121 and a lower portion 122, where the upper portion 121 is connected to an upper end of the lower portion 122, and the upper portion 121 is smaller than the lower portion 122 in size. The upper portion 121 may be understood as the outer wall of a portion of the given silicon pillar 120 including the top end being recessed inward, and compared with this portion of the original silicon pillar 120, the formed upper portion 121 is equivalent to forming the recessed region 123 encircling the given silicon pillar 120. On this basis, the second dielectric layer 520 covers the top surface and the partially removed side surface of the given silicon pillar 120 (i.e., the top surface and the side surface of the upper portion 121). There is a gap G between the second dielectric layer 520 and the first spacer 210, and rest of the first dielectric layer 510 and the second dielectric layer 520 jointly constitute the dielectric layer 500.

In this embodiment, a material of the first dielectric layer 510 may be the same, but not limited thereto, as a material of the second dielectric layer 520.

In this embodiment, before Step S24, the present disclosure may further include cleaning the semiconductor structure.

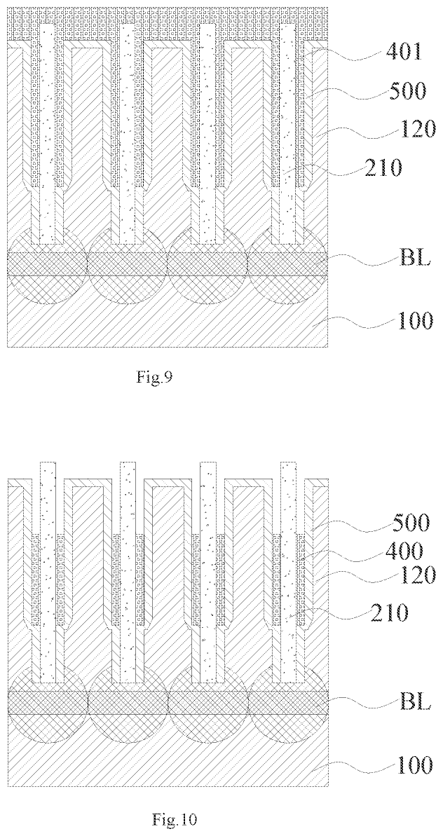

As shown in FIG. 10, a schematic cross-sectional diagram of the semiconductor structure in Step S25 is illustrated. The semiconductor structure in Step S25 includes the substrate 100, the bit line BL, the given silicon pillar 120, the first spacer 210, the dielectric layer 500, and the gate-all-around structure 400. In some embodiments, the gate-all-around structure 400 is formed in the lower space of the gap G. First, a conductive material 401 may be provided to cover the surface of the semiconductor structure, where the conductive material 401 fills the gap G (as shown in FIG. 9). Next, the conductive material 401 is etched back, such that part of the conductive material 401 is removed, and the conductive material 401 positioned in the lower space of the gap G is reserved, thereby forming the gate-all-around structure 400 encircling a periphery of the given silicon pillar 120.

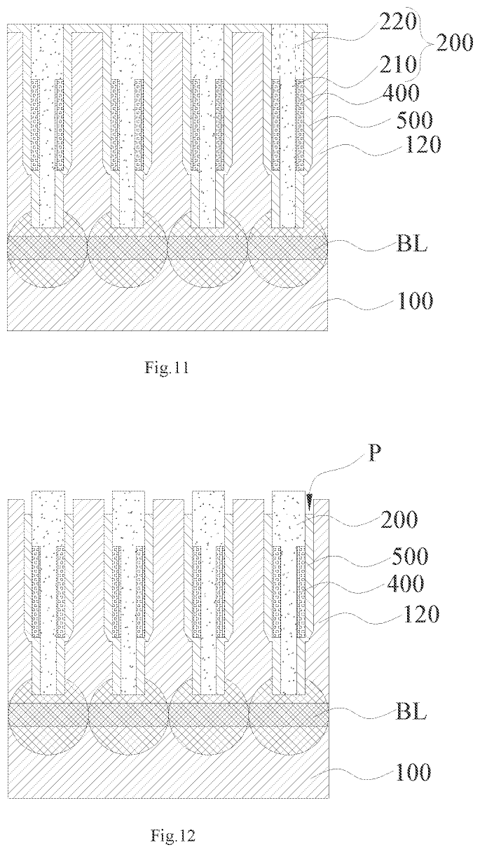

As shown in FIG. 11, a schematic cross-sectional diagram of the semiconductor structure in Step S25 is illustrated. The semiconductor structure in Step S25 includes the substrate 100, the bit line BL, the given silicon pillar 120, the first spacer 210, the dielectric layer 500, the gate-all-around structure 400, and the second spacer 220. In some embodiments, after the gate-all-around structure 400 is formed by means of etching back, the upper space of the gap G is empty due to the removal of part of the conductive material 401, and the second spacer 220 is formed by filling the upper space of the gap G with the spacer material, where the first spacer 210 and the second spacer 220 jointly constitute the spacer 200.

As shown in FIG. 12, a schematic cross-sectional diagram of the semiconductor structure in Step S3 is illustrated. The semiconductor structure in Step S3 includes the substrate 100, the bit line BL, the given silicon pillar 120, the dielectric layer 500, the gate-all-around structure 400, and the spacer 200. In some embodiments, in Step S3, the top surface of the given silicon pillar 120 and the dielectric layer 500 on the partial side surface adjacent to the top surface are etched and removed, such that a pit P is formed around an top end of the given silicon pillar 120, where a side wall of the pit P is defined by the side surface of the spacer 200 (the second spacer 220) and the side surface of the given silicon pillar 120, and a bottom wall of the pit P is defined by the top surface of the dielectric layer 500 (the second dielectric layer 520) partially removed in Step S3.

As shown in FIG. 5 and FIG. 8, the thickness of the second dielectric layer 520 formed on the top surface of the given silicon pillar 120 in Step S21 may be smaller than that of the first dielectric layer 510 formed on the top surface of the given silicon pillar 120 in Step S24, such that the top of the first spacer 210 is higher than the top surface of the second dielectric layer 520. On this basis, as shown in FIG. 11, after Step S26 and before Step S3, the top of the spacer 200 may be subjected to polishing such as chemical mechanical polishing, such that the top surface of the polished spacer 200 is flush with the top surface of the second dielectric layer 520.

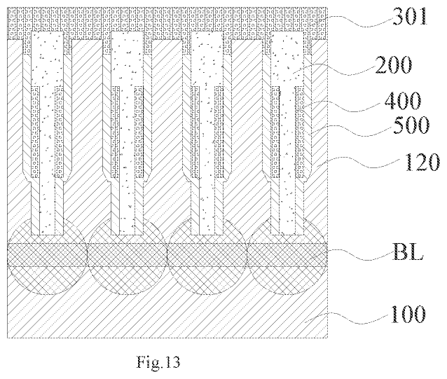

Referring to FIG. 2, a schematic cross-sectional diagram of the semiconductor structure in Step S4 is illustrated. The semiconductor structure in Step S4 includes the substrate 100, the bit line BL, the given silicon pillar 120, the dielectric layer 500, the gate-all-around structure 400, the spacer 200, and the conductive layer 300. In some embodiments, as shown in FIG. 13, first, a conductive material 301 may be provided to cover the surface of the semiconductor structure, where the conductive material 301 fills the pit P. Next, the conductive material 301 positioned above the spacer 200 is removed by polishing, and only the conductive material 301 covering the top surface of the given silicon pillar 120 and the conductive material 301 filling the pit P are reserved. In this way, the conductive layer 300 covering the top surface of the given silicon pillar 120 and the partial side surface thereof adjacent to the top surface is formed, and the top surface of rest of the conductive layer 300 is flush with the top surface of the spacer 200.

It is to be noted here that the methods for fabricating a semiconductor structure shown in the drawings and described in this specification are only a few examples in various fabrication methods that can employ the principles of the present disclosure. It is to be clearly understood that the principles of the present disclosure are in no way limited to any details or steps of the fabrication methods illustrated in the drawings or described in this specification.

In conclusion, in the semiconductor structure provided by the present disclosure, a conductive layer 300 is arranged at a top of the given silicon pillar 120, where the conductive layer 300 covers a top surface of the given silicon pillar 120 and a partial side surface thereof adjacent to the top surface, and the conductive layer 300 is configured to contact with a capacitor. Through the above design, a contact area of an indirect electric contact between the given silicon pillar 120 and the capacitor can be increased by means of a design where the conductive layer 300 covers the top surface and the partial side surface of the given silicon pillar 120, such that a contact resistance between the given silicon pillar 120 and the capacitor is reduced, and device performance is improved.

Exemplary embodiments of the semiconductor structure and the method for fabricating the semiconductor structure proposed in the present disclosure are described and/or illustrated in detail above. However, the embodiments of the present disclosure are not limited to the particular embodiments described herein, on the contrary, constituent parts and/or steps of each of the embodiments may be used independently and separately from other constituent parts and/or steps described herein. Each constituent part and/or each step of one embodiment may also be used in combination with other constituent parts and/or steps of other embodiments. When elements/constituent parts/etc. described and/or illustrated herein are introduced, terms “one,” “a,” “above,” and the like are intended to mean that there are one or more of the elements/constituent parts/etc. The terms “comprising”, “including” and “having” are intended to indicate an open-ended inclusive meaning and mean that there may be additional elements/constituent parts/etc. in addition to the listed elements/constituent parts/etc. In addition, the terms “first”, “second”, etc. in the claims and the specification are used only as marks, and are not numerical limitations on their objects.

Although the semiconductor structure and the method for fabricating the semiconductor structure proposed in the present disclosure have been described according to different particular embodiments, those skilled in the art will recognize that changes may be made to implementations of the present disclosure within the spirit and scope of the claims.

What is claimed is:

1. A semiconductor structure, comprising a substrate, wherein a plurality of trenches are crisscross arranged in the substrate, such that a plurality of silicon pillars are formed on the substrate, and each of the plurality of trenches is filled with a spacer, a conductive layer being arranged at a top of a given one of the plurality of silicon pillars, the conductive layer covering a top surface of the given silicon pillar and a partial side surface thereof adjacent to the top surface, and the conductive layer being configured to contact with a capacitor.

2. The semiconductor structure according to claim 1, wherein a top surface of the spacer is flush with a top surface of the conductive layer.

3. The semiconductor structure according to claim 1, wherein a material of the spacer is silicon nitride.

4. The semiconductor structure according to claim 1, wherein a material of the conductive layer is titanium nitride or tungsten.

5. The semiconductor structure according to claim 1, wherein a gate-all-around structure is arranged around the given silicon pillar, a dielectric layer being arranged between the gate-all-around structure and the given silicon pillar.

6. The semiconductor structure according to claim 5, wherein the dielectric layer covers rest of side surface of the given silicon pillar not covered by the conductive layer.

7. The semiconductor structure according to claim 6, wherein the dielectric layer and the conductive layer are equal in thickness.

8. The semiconductor structure according to claim 5, wherein the given silicon pillar is provided with an upper portion and a lower portion, the upper portion being connected to an upper end of the lower portion, the upper portion being smaller than the lower portion in size, and the gate-all-around structure being arranged around the upper portion and being positioned below the conductive layer at intervals.

9. The semiconductor structure according to claim 5, wherein a material of the gate-all-around structure is titanium nitride or tungsten.

10. The semiconductor structure according to claim 5, wherein a material of the dielectric layer is silicon oxide.

11. A method for fabricating a semiconductor structure, comprising:
providing a substrate, wherein a plurality of trenches are crisscross arranged in the substrate, such that a plurality of silicon pillars are formed on the substrate;
forming a spacer, wherein the spacer is filled in a given one of the plurality of trenches, and a top surface of the spacer being exposed in the given trench;
removing the spacer on a top surface of the given silicon pillar and the spacer on a partial side surface thereof adjacent to the top surface, and forming a pit around an top end of the given silicon pillar; and
forming a conductive layer on a surface of the substrate, wherein the conductive layer covers the top surface of the given silicon pillar and a partial side surface thereof adjacent to the top surface.

12. The method for fabricating a semiconductor structure according to claim 11, further comprising:
forming a gate-all-around structure and a dielectric layer, the gate-all-around structure encircling the given silicon pillar, the dielectric layer being arranged between the gate-all-around structure and the given silicon pillar, and the dielectric layer covering a side surface and the top surface of the given silicon pillar and being positioned between the gate-all-around structure and the given silicon pillar.

13. The method for fabricating a semiconductor structure according to claim 12, wherein the forming a gate-all-around structure, a dielectric layer and a spacer comprises:
covering the top surface and the side surface of the given silicon pillar with a dielectric material to form a first dielectric layer;
filling each of the plurality of trenches with a spacer material to form a first spacer;
removing the first dielectric layer positioned on the top surface of the given silicon pillar and the first dielectric layer positioned on the a partial side surface thereof adjacent to the top surface;
partially removing the side surface of the given silicon pillar not covered by the first dielectric layer, and forming a second dielectric layer on the top surface and the partially removed side surface of the given silicon pillar, there being a gap between the second dielectric layer and the first spacer, and rest of first dielectric layer and the second dielectric layer jointly constituting the dielectric layer;
forming the gate-all-around structure encircling the given silicon pillar in a lower space of the gap; and
filling an upper space of the gap with a spacer material to form a second spacer, the first spacer and the second spacer jointly constituting the spacer.

14. The method for fabricating a semiconductor structure according to claim 13, wherein before the forming a second dielectric layer, the method further comprises cleaning the semiconductor structure.

15. The method for fabricating a semiconductor structure according to claim 13, wherein a thickness of the second dielectric layer formed on the top surface of the given silicon pillar is smaller than a thickness of the first dielectric layer formed on the top surface of the given silicon pillar, such that a top of the first spacer is higher than a top surface of the second dielectric layer; wherein before the removing the dielectric layer on the top surface of the given silicon pillar and the dielectric layer on the partial side surface thereof adjacent to the top surface, the method further comprises grinding a top of the first spacer until the top of the first spacer is flush with the top surface of the second dielectric layer.
